(19) United States
(12) Patent Application Publication
(10) Pub. No.: US 2014/0174528 A1
(43) Pub. Date: Jun. 26, 2014

(54) FLEXIBLE ORGANIC ELECTRONIC DEVICE

(71) Applicant: FUJIFILM CORPORATION, Tokyo (JP)

(72) Inventors: Kohei HIGASHI, Ashigarakami-gun (JP); Yoshiki Maehara, Ashigarakami-gun (JP); Jiro Tsukahara, Ashigarakami-gun (JP)

(73) Assignee: FUJIFILM CORPORATION, Tokyo (JP)

(21) Appl. No.: 14/192,157

(22) Filed: Feb. 27, 2014

Related U.S. Application Data
(63) Continuation of application No. PCT/JP2012/005448, filed on Aug. 29, 2012.

(30) Foreign Application Priority Data
Sep. 2, 2011 (JP) 2011-191689
Mar. 26, 2012 (JP) 2012-069122

(51) Int. Cl. H01L 51/44

(52) U.S. Cl. CPC H01L 51/44
USPC 136/256; 136/259

(57) ABSTRACT

An organic electronic device includes at least an organic-inorganic layered barrier layer, a plastic support, a transparent electrode layer, an organic active layer, a metal electrode layer and an upper sealing member, and contains a strong acid polymer, wherein an n-type oxide semiconductor layer is provided adjacent to the metal electrode layer on the plastic support-side of the metal electrode layer.

### TECHNICAL FIELD

The present invention relates to a flexible organic thin-film electronic device, such as an organic thin-film solar battery, having an organic-inorganic layered barrier layer.

### BACKGROUND ART

In recent years, flexible electronic devices as soft matters are attracting attention. In particular, there are higher and higher expectations for flexible organic electronic devices that are expected to achieve lightweight and low production cost, specifically, organic thin-film solar batteries and flexible organic EL devices (or organic electroluminescence devices).

A typical structure of flexible organic electronic devices includes an electron-conductive organic thin film and/or a hole-conductive organic thin film disposed between two dissimilar electrodes, at least one of which is transparent. Such flexible organic electronic devices have an advantage that the production thereof is easier than production of inorganic devices formed by using silicon, etc., thereby achieving lower production cost, and it is desired to put the flexible organic electronic devices into practical use.

Organic electronic devices, in general, degrade due to moisture and oxygen in air. In order to realize the flexible organic electronic devices, a gas barrier substrate and a gas barrier sealing means for protecting the device from moisture and oxygen in air are necessary. Plastic films typically show poor gas barrier performance and are not suitable for use as a substrate for a flexible organic electronic device.

Japanese Unexamined Patent Publication No. 2010-087339 discloses an organic thin-film solar battery with improved storage stability that is achieved by using a plastic film provided with a gas barrier layer having a layered structure of an organic layer and an inorganic layer (which will hereinafter be referred to as “organic-inorganic layered barrier layer”) as the substrate.

On the other hand, organic electronic devices often use polyethylenedioxythiophene/polystyrene sulfonate complex (which will hereinafter be referred to as “PEDOT-PSS”), which is a strong acid polymer, as a hole-transporting material or a conductive material, thereby providing good device characteristics (such as high luminous efficiency, high power generation efficiency, etc.)

### DISCLOSURE OF INVENTION

However, there is a problem that organic electronic devices that use a plastic film provided with an organic-inorganic layered barrier layer as the substrate and contain a strong acid polymer (such as PEDOT-PSS) as the hole-transporting material or conductive material do not exhibit expected good device characteristics.

Therefore, it is desired to develop an organic electronic device that contains a strong acid polymer and includes an organic-inorganic layered barrier layer, and exhibits good device characteristics and good storage stability at the same time.

A problem to be solved by the invention is to providing an organic electronic device that contains a strong acid polymer and includes an organic-inorganic layered barrier layer, and exhibits good device characteristics and good storage stability at the same time.

The present inventors have found through intense study that the problem to be solved by the invention can be solved by providing an n-type oxide semiconductor layer between a negative electrode and a layer containing a strong acid polymer, such as PEDOT-PSS, and have accomplished the present invention.

The constitution of the invention is as described below.

The organic electronic device of the invention is an organic electronic device including at least an organic-inorganic layered barrier layer, a plastic support, a transparent electrode layer, an organic active layer, a metal electrode layer and an upper sealing member, and contains a strong acid polymer, the organic electronic device further including an n-type oxide semiconductor layer that is provided adjacent to the metal electrode layer on a side of the metal electrode layer nearer to the plastic support.

It is preferred that the n-type oxide semiconductor is titanium oxide or zinc oxide.

It is preferred that the strong acid polymer is polystyrene sulfonate.

Alternatively, it is preferred that the strong acid polymer is polyethylenedioxythiophene/polystyrene sulfonate complex.

It is preferred that the strong acid polymer is provided in the transparent electrode layer or adjacent to the transparent electrode layer.

It is preferred that the transparent electrode layer is formed by a combination of a conductive stripe formed by a plurality of conductive lines arranged in a stripe pattern and a transparent conductive material.

It is preferred that the conductive lines are made of silver.

Alternatively, it is preferred that the conductive lines are made of copper.

It is preferred that the organic-inorganic layered barrier layer is provided between the plastic support and the transparent electrode layer.

It is preferred that a layer of the organic-inorganic layered barrier layer adjacent to the transparent electrode layer is an organic layer.

In a case where the organic active layer of the organic electronic device of the invention is a photoelectric conversion layer, the organic electronic device functions as an organic thin-film solar battery.

It is preferred that the photoelectric conversion layer is a bulk hetero layer.

The organic electronic device of the invention having the above-described constitution has good device characteristics and good storage stability.

Therefore, the organic electronic device of the invention is useful to form a lightweight and flexible organic thin-film solar battery or organic EL device. An organic EL device using the invention has excellent luminous efficiency, and an organic thin-film solar battery using the invention has excellent power generation efficiency.

Using an optically transparent and flexible resin film as the support allows providing a flexible organic electronic device. Such a flexible organic electronic device allows producing a lightweight and flexible electronic device in a simple manner.

According to the invention, an organic electronic device having good device characteristics and good storage stability, such as an organic EL device having high storage stability and high luminous efficiency, or an organic thin-film solar battery having high storage stability and high power generation efficiency can be provided.

### BRIEF DESCRIPTION OF THE DRAWINGS

FIG. 1 is a schematic sectional view illustrating a first embodiment of an organic electronic device of the present invention,

FIG. 2 is a schematic sectional view illustrating a second embodiment of the organic electronic device of the invention,

FIG. 3 is a schematic sectional view illustrating a preferred embodiment of a transparent electrode layer to which the organic electronic device of the invention is applied, and

FIG. 4 is a schematic plan view illustrating the preferred embodiment of the transparent electrode layer to which the organic electronic device of the invention is applied.

### DESCRIPTION OF PREFERRED EMBODIMENTS

Hereinafter, the content of the present invention will be described in detail.

It should be noted that each numerical range expressed herein by a lower limit value and an upper limit value connected by “to” includes the lower limit value and the upper limit value.

### Organic Electronic Device

An organic electronic device of the invention includes at least an organic-inorganic layered barrier layer, a plastic support, a transparent electrode layer, an organic active layer, a metal electrode layer and an upper sealing member, and contains a strong acid polymer, wherein an n-type oxide semiconductor layer is provided adjacent to the metal electrode layer on the side of the metal electrode layer nearer to the plastic support.

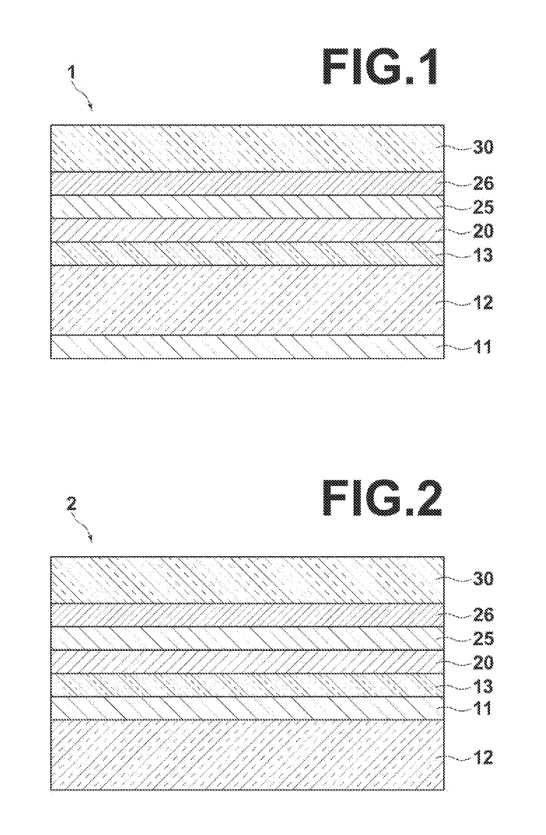

FIG. 1 is a sectional view schematically illustrating the layer structure of a first embodiment of the organic electronic device of the invention. An organic electronic device 1 of the first embodiment includes an organic-inorganic layered barrier layer 11, a plastic support 12, a transparent electrode layer 13, an organic active layer 20, an n-type oxide semiconductor layer 25, a metal electrode layer 26 and an upper sealing member 30 which are disposed in this order.

FIG. 2 is a sectional view schematically illustrating the layer structure of a second embodiment of the organic electronic device of the invention. An organic electronic device 2 of the second embodiment includes the plastic support 12, the organic-inorganic layered barrier layer 11, the transparent electrode layer 13, the organic active layer 20, the n-type oxide semiconductor layer 25, the metal electrode layer 26 and the upper sealing member 30 which are disposed in this order.

In the organic electronic devices of the first and second embodiments, the transparent electrode layer 13 and/or the organic active layer 20 contains a strong acid polymer.

The organic electronic devices of the first and second embodiments may further include, between the above-described layers or on the outer side of the device, various functional layers and/or another support. Preferred examples of the functional layers are the same as those described later with respect to the plastic support.

Now, the individual layers forming the organic electronic device of the invention are described in detail.

### Organic-Inorganic Layered Barrier Layer

The organic-inorganic layered barrier layer is a layered body formed by at least one layer of organic region or organic layer and at least one layer of inorganic region or inorganic layer.

In the case where the organic-inorganic layered barrier layer is formed by the organic region and the inorganic region, the organic-inorganic layered barrier layer may be a so-called gradient material layer, where one of the regions changes over to the other of the regions in a continuous manner in the film thickness direction. Examples of the gradient material include materials disclosed in a paper by Kim, et al., Journal of Vacuum Science and Technology A, Vol. 23, pp. 971-977 (2005, American Vacuum Society), a continuous layer including an organic layer and an inorganic layer with no interface therebetween disclosed in U.S. Patent Application Publication No. 2004046497, etc.

In the case where there are two or more organic layers or organic regions, or two or more inorganic layers or inorganic regions, it is usually preferable that the organic layer (s) and the inorganic layer(s) are alternately disposed.

In this case, it is preferable that there is a clear interface between the organic layer and the inorganic layer.

Specific examples of the organic layer and the inorganic layer and the method for forming the layered structure are disclosed in Japanese Unexamined Patent Publication No. 2010-087339. It should be noted that the term “organic polymer layer” used in the above document corresponds to the term “organic layer” used herein.

The organic-inorganic layered barrier layer may be disposed on the support of the organic electronic device, or may be formed on another support and bonded to the organic electronic device. In the case where the organic-inorganic layered barrier layer is disposed on the support of the organic electronic device, the organic electronic device may be formed on the barrier layer-side surface or on the opposite side from the barrier layer.

### Plastic Support

As the plastic support, it is preferable to use a plastic film that is excellent in transparency, strength and ease of handling, and is relatively inexpensive.

The material, thickness, etc., of the plastic film used as the support are not particularly limited and can be selected as appropriate depending on the purpose, as long as the plastic film can hold a conductive stripe, bus lines, a transparent conductive material layer, etc., which will be described later.

Specific examples of the material of the plastic film usable as the support include thermoplastic resins, such as polyester resin, methacryl resin, methacrylate-maleate copolymer, polystyrene resin, transparent fluorine resin, polyimide, fluorinated polyimide resin, polyamide resin, polyamide-imide resin, polyetherimide resin, cellulose acylate resin, polyurethane resin, polyetheretherketone resin, polycarbonate resin, alicyclic polyolefin resin, polyarylate resin, polyethersulfone resin, polysulfone resin, cycloolefin copolymer, fluorene ring-modified polycarbonate resin, alicyclic modified polycarbonate resin, fluorene ring-modified polyester resin, acryloyl compound, etc.

The plastic film substrate is preferably made of a heat-resisting material. Specifically, it is preferred that the plastic film substrate is formed using a material that has heat resistance meeting at least one of the following physical properties: a glass transition temperature (Tg) of not lower than 60° C. and a linear thermal expansion coefficient of not higher than 40 ppm/° C., and is highly transparent to an exposure wavelength, as mentioned above.

It should be noted that the Tg and the linear expansion coefficient of the plastic film are measured according to the “Testing methods for transition temperatures of plastics” of JIS K 7121 and the “Testing method for linear thermal expansion coefficient of plastics by thermomechanical analysis” of JIS K 7197. Values of the Tg and the linear expansion coefficient of the plastic film used in the invention were measured according to these methods.

The Tg and the linear expansion coefficient of the plastic film can be adjusted using additives, etc. Examples of the highly heat-resistant thermoplastic resin include polyethylene terephthalate (PET: 65° C.), polyethylene naphthalate (PEN: 120° C.), polycarbonate (PC: 140° C.), alicyclic polyolefin (for example, ZEONOR 1600 available from Zeon Corporation: 160° C.), polyarylate (PAr: 210° C.), polyethersulfone (PES: 220° C.), polysulfone (PSF: 190° C.), cycloolefin copolymer (COC (a compound disclosed in Japanese Unexamined Patent Publication No. 2001-150584): 162° C.), fluorene ring-modified polycarbonate (BCF-PC (a compound disclosed in Japanese Unexamined Patent Publication No. 2000-227603): 225° C.), alicyclic modified polycarbonate (IP-PC (a compound disclosed in Japanese Unexamined Patent Publication No. 2000-227603): 205° C.), acryloyl compound (a compound disclosed in Japanese Unexamined Patent Publication No. 2002-080616: 300° C. or more), polyimide, etc. (In the above description, the numerical value shown together with the abbreviation, etc., of each resin in the parentheses is the Tg of the resin.) All the resins listed above are suitable for use as the base material in the invention. In particular, for applications where transparency is required, alicyclic polyolefin, or the like, is preferably used.

In the invention, the plastic film is required to be transparent to light. More specifically, the optical transmittance of the plastic film to light in the wavelength range from 400 nm to 1000 nm is preferably not less than 80%, more preferably not less than 85%, or even more preferably not less than 90%.

It should be noted that the optical transmittance can be found according to the method of JIS-K7105, namely, by measuring a total optical transmittance and an amount of scattered light using an integrating-sphere transmittance measuring device, and subtracting a diffuse transmittance from the total optical transmittance. Values of the optical transmittance used herein were calculated according to this method.

The thickness of the plastic film is not particularly limited; however, the thickness of the plastic is typically in the range from 1 μm to 800 μm, and preferably in the range from 10 μm to 300 μm.

A known functional layer may be provided on the rear surface (on the side where the conductive stripe is not formed) of the plastic film. Examples of the functional layer include a gas barrier layer, a matting agent layer, an antireflection layer, a hard coating layer, an antifog layer, an antifouling layer, etc. Other functional layers are described in detail in paragraphs [0036] to [0038] of Japanese Unexamined Patent Publication No. 2006-289627.

### Adhesion Enhancing Layer/Undercoating Layer

The plastic film substrate may include an adhesion enhancing layer or an undercoating layer.

The adhesion enhancing layer must contain a binder polymer, and may contain, as necessary, a matting agent, a surfactant, an antistatic agent, particulates for controlling refractive index, etc.

The binder polymer used in the adhesion enhancing layer is not particularly limited, and may be selected, as appropriate, from the following acrylic resins, polyurethane resins, polyester resins and rubber resins, for example.

Acrylic resins are polymers composed of acrylic acid, methacrylic acid or derivatives thereof. Specific examples thereof include polymers composed mainly of acrylic acid, methacrylic acid, methylmethacrylate, ethylacrylate, butylacrylate, 2-ethylhexylacrylate, acrylamide, acrylonitrile, hydroxyl acrylate, etc., and formed through copolymerization between these compounds and a monomer (such as styrene, divinylbenzene, etc.) that is copolymerizable with these compounds.

Polyurethane resin is the collective term for polymers having urethane bonds in the main chain, which are typically obtained through a reaction between a polyisocyanate and a polyol. Examples of the polyisocyanate include TDI (Tolylene Diisocyanate), MDI (Methyl Diphenyl Isocyanate), HDI (Hexylene diisocyanate), IPDI (Isophoron diisocyanate), etc. Examples of the polyol include ethylene glycol, propylene glycol, glycerin, hexanetriol, trimethylolpropane, pentaerythritol, etc. Further, as the isocyanate of the invention, a polymer obtained by performing chain extension to increase the molecular weight on a polyurethane polymer that is obtained through a reaction between a polyisocyanate and a polyol may also be usable.

Polyester resin is the collective term for polymers having ester bonds in the main chain, which are typically obtained through a reaction between a polycarboxylic acid and a polyol. Examples of the polycarboxylic acid includes fumaric acid, itaconic acid, adipic acid, sebacic acid, terephthalic acid, isophthalic acid, naphthalenedicarboxylic acid, etc. Examples of the polyol are as described above.

The rubber resin of the invention refers to a diene synthetic rubber among synthetic rubbers. Specific examples of the diene synthetic rubber include polybutadiene, styrene-butadiene copolymer, styrene-butadiene-acrylonitrile copolymer, styrene-butadiene-divinylbenzene copolymer, butadiene-acrylonitrile copolymer, polychloroprene, etc.

The thickness of coating of the adhesion enhancing layer or the undercoating layer after drying is preferably in the range from 50 nm to 2 μm. If the layer has a layered structure, it is preferable that the total thickness of layers forming the layered structure is within the above range.

It should be noted that, if the support is used as a tentative support, a treatment to make the support easily peelable may be applied to the surface of the support.

### Transparent Electrode Layer

The transparent electrode layer of the invention is a layer containing at least a transparent conductive material. Usually, the transparent electrode layer of an organic EL device is a negative electrode, and the transparent electrode layer of an organic thin-film solar battery is a positive electrode. The transparent electrode layer 13 is required to be transparent to a range of an emission spectrum or an action spectrum of an organic electronic device to which the transparent electrode layer is applied, and is usually required to have excellent optical transparency to light in the range from visible light to near-infrared light. Specifically, when a layer of a transparent conductive material having a thickness of 0.1 μm is formed, the formed layer has an average optical transmittance in the wavelength range from 400 nm to 800 nm of not less than 50%, preferably not less than 75%, or more preferably not less than 85%.

The transparent conductive material used in the transparent electrode layer is required to be highly conductive, and preferably has a specific resistance after film formation of not higher than 8×10⁻³Ω·cm.

Examples of the transparent conductive material having such a specific resistance include metal oxides (such as indium-tin oxide, antimony-tin oxide, aluminum-zinc oxide, boron-zinc oxide, tin fluoride oxide, etc.), a dispersion of a conductive nanomaterial (such as silver nanowire, carbon nanotube, graphene, etc.) in an acrylic polymer, or the like, and conductive polymers (such as polythiophene, polypyrrol, polyaniline, polyphenylenevinylene, polyphenylene, polyacethylene, polyquinoxaline, polyoxadiazole, polybenzothiadiazole, etc., and polymers having two or more of these conductive skeletons, etc.)

Among them, polythiophene is preferable, and polyethylenedioxythiophene is particularly preferable. These polythiophenes are usually subjected to partial oxidation to provide conductivity. The conductivity of conductive polymers can be adjusted by the degree of partial oxidation (amount of doping). The larger the amount of doping, the higher the conductivity. Polythiophenes become cationic through the partial oxidation and therefore have a counter anion to neutralize the charge. An example of such a polythiophene is polyethylenedioxythiophene with polystyrene sulfonate as the counter ion (PEDOT-PSS).

The PEDOT-PSS may contain a high-boiling point organic solvent in order to increase the conductivity. Examples of the high-boiling point organic solvent include ethylene glycol, diethylene glycol, dimethylsulfoxide, N-methylpyrrolidone, 1,3-dimethyl-2-imidazolidinone, etc.

Examples of commercially-available PEDOT-PSS products that achieve the above-described specific resistance include ORGACON S-305 available from Agfa, and CLEVIOS PH500 and PH510 available from H. C. Starck.

Polystyrene sulfonate is a strong acid polymer. That is, the highly-conductive PEDOT-PSS that is particularly preferable for a flexible organic electronic device contains the strong acid polymer. The PEDOT-PSS is coated in the form of an aqueous dispersion and is subjected to dehydration annealing at a temperature in the range from 100° C. to 140° C. On a glass support, the strong acid polymer does not diffuse to exert adverse effect on the device.

On the other hand, the present inventors have found through study that, on a plastic support, since a slight amount of moisture is left in the film after the dehydration annealing, the strong acid polymer or acidic water that has been in contact with the strong acid polymer diffuses to reach the metal electrode, causing corrosion of the inner surface of the metal electrode. This results in degradation of the device characteristics.

Forming the organic electronic device on the surface of the plastic support where the organic-inorganic layered barrier is provided was effective to some extent to prevent the above-described degradation of the device characteristics; however, it was not able to eliminate the degradation of the device characteristics. On the other hand, the present inventors have found that providing an n-type oxide semiconductor layer adjacent to the metal electrode layer on the side of the metal electrode layer nearer to the plastic support significantly improves the degradation of the device characteristics.

The transparent conductive material may contain other polymers, as long as the desired conductivity is not impaired. The purposes of adding other polymers are to improve ease of coating and to increase the film strength.

Examples of the other polymers include thermoplastic resins, such as polyester resin, methacryl resin, methacrylate-maleate copolymer, polystyrene resin, transparent fluorine resin, polyimide, fluorinated polyimide resin, polyamide resin, polyamide-imide resin, polyetherimide resin, cellulose acylate resin, polyurethane resin, polyetheretherketone resin, polycarbonate resin, alicyclic polyolefin resin, polyarylate resin, polyethersulfone resin, polysulfone resin, cycloolefin copolymer, fluorene ring-modified polycarbonate resin, alicyclic modified polycarbonate resin, fluorene ring-modified polyester resin, acryloyl compound, etc., and hydrophilic polymers, such as gelatin, polyvinyl alcohol, polyacrylic acid, polyacrylamide, polyvinyl pyrrolidone, polyvinyl pyridine, polyvinyl imidazole, etc. These polymers may have a crosslinked structure to increase the film strength.

Among the transparent conductive materials, film formation of the metal oxide is achieved by sputtering or vapor deposition. Film formation of the conductive polymer and film formation of the conductive nanoparticles are achieved by coating.

The transparent electrode layer preferably has a conductive pattern containing a metal or an alloy having a specific resistance of not higher than 1×10⁻⁵Ω·cm in order to increase the conductivity. Examples of the metal forming the conductive pattern include gold, platinum, iron, copper, silver, aluminum and alloys containing these metals. More preferred examples of the metal forming the conductive pattern include copper, silver and alloys containing these metals. In view of the cost reduction of the metal material and in view of the migration resistance, copper is preferred.

The shape of the conductive pattern is not particularly limited, and may be designed to have any shape, such as a stripe, mesh, honeycomb or rhomboid pattern. An open area ratio defined by the conductive pattern is not less than 70%, or more preferably not less than 80%. Further, bus lines for power collection may be provided at regular intervals.

Examples of the method for providing the conductive pattern include vapor deposition, sputtering, printing, inkjet printing, etc., and an appropriate method is selected. In a case where the conductive pattern is formed by printing or inkjet printing, a binder may be added, as long as the desired conductivity is not impaired. Examples of the binder include thermoplastic resins, such as polyester resin, methacryl resin, methacrylate-maleate copolymer, polystyrene resin, transparent fluorine resin, polyimide, fluorinated polyimide resin, polyamide resin, polyamide-imide resin, polyetherimide resin, cellulose acylate resin, polyurethane resin, polyetheretherketone resin, polycarbonate resin, alicyclic polyolefin resin, polyarylate resin, polyethersulfone resin, polysulfone resin, cycloolefin copolymer, fluorene ring-modified polycarbonate resin, alicyclic modified polycarbonate resin, fluorene ring-modified polyester resin, acryloyl compound, etc., and hydrophilic polymers, such as gelatin, polyvinyl alcohol, polyacrylic acid, polyacrylamide, polyvinyl pyrrolidone, polyvinyl pyridine, polyvinyl imidazole, etc. These polymers may have a crosslinked structure to increase the film strength.

It is preferable to form the conductive pattern before forming the film of the transparent conductive material, since the transparent conductive material smoothes height difference due to the conductive pattern.

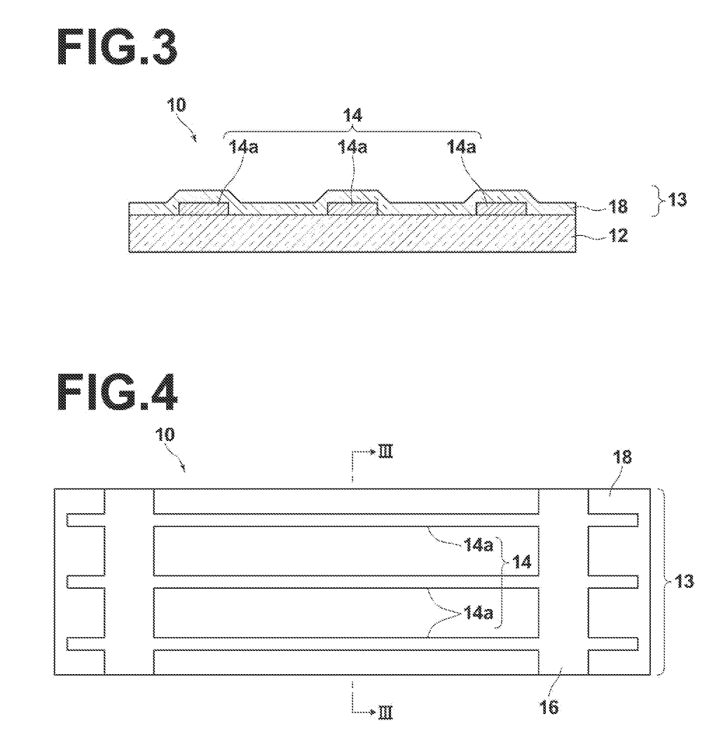

A preferred structure example of the transparent electrode layer applied to the organic electronic device of the invention is shown in FIGS. 3 and 4. FIG. 3 is a schematic sectional view illustrating the transparent electrode layer 13 formed on the support 12, and FIG. 4 is a schematic plan view of the transparent electrode layer 13 shown in FIG. 3. It should be noted that the film including the support 12 and the transparent electrode layer 13 is referred to as a transparent conductive film 10.

The transparent electrode layer 13 shown in FIG. 3 includes a conductive stripe 14 that includes a plurality of conductive lines 14a, bus lines 16 that are perpendicular to the conductive stripe 14, and a transparent conductive material layer 18 that is formed to cover the conductive stripe 14 and the bus lines 16.

It is preferable to form the transparent electrode layer by first forming the conductive pattern including the conductive stripe 14 and the bus lines 16, and then applying the conductive polymer layer to cover the conductive pattern.

### Conductive Stripe

The conductive lines 14a (which may hereinafter be referred to as “conductive stripe lines”) of the conductive stripe 14 have a film thickness of not less than 50 nm and not greater than 500 nm, a line width of not less than 0.1 mm and not greater than 1 mm in plan view, and an interval between the lines 14a of not less 3 mm and not greater than 30 mm.

Each conductive line forming the conductive stripe has a resistance value of not greater than 50Ω/cm, preferably not greater than 20Ω/cm, or more preferably not greater than 10Ω/cm. In order to achieve this level of conductivity (i.e., low resistance), each conductive stripe line needs to have a large sectional area. In order to provide a large open area ratio, a cross-sectional shape with a short length in the film-plane direction (line width) and a long length in the film-thickness direction (film thickness) is advantageous.

However, providing the conductive stripe having the above-described cross-section results in large height difference. Since the thickness of the active layer (organic layer) of an organic electronic device is as thin as 50 to 500 nm, the large height difference due to the conductive stripe is likely to cause short circuit (failure) at corners of the protrusions of the conductive stripe lines.

Therefore, it is more important to reduce the height difference due to the conductive stripe and make the corners of the protrusions of the conductive stripe lines obtuse than to increase the open area ratio, and a design where the open area ratio is somewhat sacrificed have to be adopted. Namely, a design where the cross-sectional shape has a large line width and a small film thickness is selected. The ratio between the line width and the film thickness is in the range from 20000:1 to 200:1. As the film thickness, a value of the thickest part of the line in the line width direction is used.

Depending on the method for forming the stripe, the cross-sectional shape of the conductive lines can be a rectangle, an isosceles trapezoid, an obtuse isosceles triangle, a semicircle, a figure enclosed in an arc and a chord, a deformed figure of any of these shapes, or the like. An isosceles trapezoid or an obtuse isosceles triangle, which are tapered shapes, are less likely to cause short circuit and are more preferable than a cross-sectional shape with right-angle corners of the protrusion of the line, such as a rectangle. Also, a curved or sloped cross-sectional shape with smoothed height difference is less likely to cause short circuit and is more preferable than a cross-sectional shape with clear-cut corners.

The relationship between the film thickness of the conductive lines 14a of the conductive stripe 14 and the thickness of the organic active layer may preferably be such that the former does not exceed five times the latter, or more preferably does not exceed twice the latter, for example.

In view of device characteristics (such as current-voltage characteristics), a smaller interval (pitch) between the lines 14a of the conductive stripe 14 is more advantageous. However, a smaller pitch means a smaller open area ratio, and therefore a point of compromise is selected. The pitch is determined to provide a preferred open area ratio depending on the line width of the metal thin lines.

Since the transparent electrode layer is for an organic electronic device and since the design where the open area ratio is sacrificed is adopted with respect to the relationship between the film thickness and the line width of the conductive stripe lines, a pitch of the conductive stripe lines that provides a maximum open area ratio is required. Namely, in order to ensure an open area ratio of 75% when the line width of the conductive stripe lines is 1 mm, a pitch of not less than 3 mm is required.

The present inventors have found through study that, at least for use with an organic thin-film solar battery, the transparent conductive material layer coated on the conductive stripe is required to be made of a highly conductive transparent conductive material that has a specific resistance value of not greater than 4×10⁻³Ω·cm. Specific examples of the transparent conductive material are as described above.

### Bus Lines

The transparent conductive film 10 shown in FIG. 3 includes the bus lines (thick-line conductive layer) 16, which cross the conductive stripe 14, on the support 12. The bus lines may not necessarily be provided.

In view of ensuring the conductivity necessary for the entire operating surface, the bus lines 16 are wiring containing a metal material and having a line width of not less than 1 mm and not greater than 5 mm in plan view. The line width of the bus lines is preferably not less than 1 mm and not greater than 3 mm.

The line width of the bus lines 16 may not necessarily be uniform. The bus lines and the conductive stripe may be made of the same material or different materials. Usually, the bus lines are formed to be perpendicular to the conductive stripe; however, the bus lines may cross the conductive stripe at an angle other than 90°. The preferred thickness, cross-sectional shape and material of the bus lines are the same as those described with respect to the conductive stripe.

As the interval (pitch) of the bus lines, an optimum condition at a point of compromise between the conductivity and the optical transmittance of a large area is selected, similarly to the conductive stripe. Specifically, the interval of the bus lines is determined by the conductivity of the conductive stripe connecting the bus lines adjacent to each other. Typically, the interval is selected such that the resistance value of the conductive stripe connecting two adjacent bus lines is not greater than 50Ω per line. The resistance value is preferably not greater than 20Ω, or particularly preferably not greater than 10Ω.

The pitch of the bus lines is preferably not less than 40 mm and not greater than 200 mm.

### Formation of Bus Lines

The bus lines 16 may be formed by vapor deposition, or by printing or inkjet printing. In view of costs, it is advantageous to form the conductive stripe 14 and the bus lines 16 at the same time using a material of the same composition. In a case where the conductive stripe 14 and the bus lines 16 are formed at the same time using a roll, equipment including a fixed mask for forming the stripe and a movable mask for forming the bus lines is necessary.

### Organic Active Layer

In the invention, the organic active layer refers to an organic material layer bearing the function of the organic electronic device. Examples of the organic active layer include a hole-transporting layer, a hole-injection layer, a hole-blocking layer, an electron-transporting layer, an electron-injection layer, an electron-blocking layer, a light-emitting layer, a photoelectric conversion layer, etc. An organic EL device includes alight-emitting layer, and an organic thin-film solar battery includes a photoelectric conversion layer. In some cases, a layered body including a hole-transporting layer and an electron-transporting layer may also serve as a light-emitting layer or a photoelectric conversion layer.

Now, the organic active layer is described in detail with taking the case of an organic thin-film solar battery as an example.

### Electron-Blocking Layer

An electron-blocking layer is a hole-transporting layer that is disposed between the transparent electrode layer and the photoelectric conversion layer and has a function to block migration of electrons from the photoelectric conversion layer to the transparent electrode layer. A material having the function to block migration of electrons is an organic compound that has a HOMO level of not greater than 5.5 eV and a LUMO level of not greater than 3.3 eV.

Specific examples of such an organic compound include aromatic amine derivatives, thiophene derivatives, condensed aromatic compounds, carbazole derivatives, polyanilines, polythiophenes, polypyrrols, etc. Besides them, a group of compounds disclosed as “Hole Transport material” in Chem. Rev., Vol. 107, pp. 953-1010, 2007 is also applicable.

Among them, polythiophenes are preferable, and polyethylenedioxythiophene is more preferable. The polyethylenedioxythiophene may be subjected to doping (partial oxidation), as long as a volume resistance of not lower than 10 Qcm is maintained. In this case, the polyethylenedioxythiophene may have a counter anion derived from a perchloric acid, a polystyrene sulfonate, or the like, to neutralize the charge.

That is, as the electron-blocking layer, PEDOT-PSS having high resistance is particularly preferable. Even with a device structure where the transparent electrode layer is made of indium-tin oxide, use of PEDOT-PSS, which is the particularly preferable electron-blocking layer material, leads to the problem of corrosion of the metal electrode layer, as described above with respect to the transparent conductive material. To solve this problem, it is again effective to provide the above-described n-type oxide semiconductor layer.

In view of the above-described fact, it is inferred to be effective, with respect to an organic electronic device formed on a plastic substrate doped with some strongly acidic material (in particular, a strong acid polymer), which is not limited to PEDOT-PSS, to provide the n-type oxide semiconductor layer adjacent to the metal electrode layer on the side of the metal electrode layer nearer to the plastic support.

The thickness of the electron-blocking layer is preferably not less than 0.1 nm and not greater than 50 nm, or more preferably in the range from 1 nm to 20 nm.

### Hole-Transporting Layer

A hole-transporting layer contains a hole-transporting material.

The hole-transporting material is a π electron conjugated compound having a HOMO level in the range from 4.5 eV to 6.0 eV. Specific examples thereof include conjugated polymers coupled with various arenes (such as thiophene, carbazole, fluorene, silafluorene, thienopyrazine, thienobenzothiophene, dithienosilole, quinoxaline, benzothiadiazole, thienothiophene, etc.), phenylenevinylene polymers, porphyrins, phthalocyanines, etc. Besides them, a group of compounds disclosed as “Hole Transport material” in Chem. Rev., Vol. 107, pp. 953-1010, 2007, and porphyrin derivatives disclosed in Journal of the American Chemical Society, Vol. 131, p. 16048, 2009, are also applicable.

Among them, conjugated polymers coupled with a building block selected from the group consisting of thiophene, carbazole, fluorene, silafluorene, thienopyrazine, thienobenzothiophene, dithienosilole, quinoxaline, benzothiadiazole and thienothiophene are particularly preferable. Specific examples thereof include poly3-hexylthiophene, poly3-octylthiophene, various polythiophene derivatives disclosed in Journal of the American Chemical Society, Vol. 130, p. 3020, 2008, PCDTBT disclosed in Advanced Materials, Vol. 19, p. 2295, 2007, PCDTQx, PCDTPP, PCDTPT, PCDTBX and PCDTPX disclosed in Journal of the American Chemical Society, Vol. 130, p. 732, 2008, PBDTTT-E, PBDTTT-C and PBDTTT-CF disclosed in Nature Photonics, Vol. 3, p. 649, 2009, and PTB7 disclosed in Advanced Materials, Vol. 22, pp. 1-4, 2010.

The thickness of the hole-transporting layer is preferably in the range from 5 to 500 nm, or particularly preferably in the range from 10 to 200 nm.

It should be noted that a hole-injection layer is encompassed by the concept of the hole-transporting layer.

### Electron-Transporting Layer

An electron-transporting layer is made of an electron-transporting material. The electron-transporting material is a π electron conjugated compound having a LUMO level in the range from 3.5 eV to 4.5 eV. Specific examples thereof include fullerenes and derivatives thereof, phenylenevinylene polymers, naphthalenetetracarboxylic imide derivatives, perylenetetracarboxylic imide derivatives, etc. Among them, fullerene derivatives are preferable. Specific examples of the fullerene derivatives include C₆₀, phenyl-C₆₁-methyl acetate (a fullerene derivative called PCBM, [60]PCBM or PC₆₁BM in the literature), C₇₀, phenyl-C₇₁-methyl acetate (a fullerene derivative often called PCBM, [70]PCBM or PC₇₁BM in the literature), fullerene derivatives disclosed in Advanced Functional Materials, Vol. 19, pp. 779-788, 2009, and a fullerene derivative SIMEF disclosed in Journal of the American Chemical Society, Vol. 131, p. 16048, 2009.

The thickness of electron-transporting layer is preferably in the range from 5 to 500 nm, or particularly preferably in the range from 10 to 200 nm.

It should be noted that an electron-injection layer and a hole-blocking layer are encompassed by the concept of the electron-transporting layer.

### Photoelectric Conversion Layer

A photoelectric conversion layer may have a planar heterostructure including a hole-transporting layer and an electron-transporting layer, or a bulk heterostructure made of a mixture of a hole-transporting material and an electron-transporting material. In the case where the photoelectric conversion layer has a planar heterostructure, the hole-transporting layer is located on the positive electrode side and the electron-transporting layer is located on the negative electrode side. Alternatively, the photoelectric conversion layer may have a hybrid structure including a bulk hetero layer as an intermediate layer in a planar heterostructure.

The bulk hetero layer is a photoelectric conversion layer made of a mixture of a hole-transporting material and an electron-transporting material. The mixing ratio between the hole-transporting material and the electron-transporting material contained in the bulk hetero layer is adjusted such that the maximum conversion efficiency is achieved. The mixing ratio between the hole-transporting material and the electron-transporting material is usually selected to be in the range from 10:90 to 90:10 in mass ratio. Formation of such a mixed organic layer may be achieved, for example, by a vacuum co-evaporation method. Alternatively, formation of the mixed organic layer may be achieved by solvent coating using a solvent in which both the organic materials, i.e., the hole-transporting material and the electron-transporting material dissolve. A specific example of the solvent coating will be described later.

The thickness of the bulk hetero layer 24 is preferably in the range from 10 nm to 500 nm, or particularly preferably in the range from 20 nm to 300 nm.

The hole-transporting material and the electron-transporting material in the bulk hetero layer may be mixed completely uniformly, or may be phase-separated with a domain size in the range from 1 nm to 1 μm. The phase-separated structure may be a random structure or an ordered structure. When an ordered structure is formed, formation of the ordered structure may be achieved by a top-down approach, such as nanoimprinting, or a bottom-up approach, such as self-organization. Examples of the hole-transporting material and the electron-transporting material used in the bulk hetero layer are the same as those described above with respect to the hole-transporting layer and the electron-transporting layer.

### N-Type Oxide Semiconductor Layer

In the invention, the inorganic oxide layer is an electron-transporting layer, and the material forming the inorganic oxide layer is an n-type inorganic oxide semiconductor (such as titanium oxide, zinc oxide, tin oxide, tungsten oxide, etc.) Among them, titanium oxide and zinc oxide are preferable.

The thickness of the n-type oxide semiconductor (inorganic electron-transporting layer) is in the range from 1 nm to 30 nm, and preferably in the range from 2 nm to 15 nm. The electron-transporting layer made of the n-type oxide semiconductor can be preferably formed by any of various wet film-forming methods, dry film-forming methods, such as vapor deposition or sputtering, a transfer method, printing, etc. In particular, a method of forming a zinc oxide layer disclosed in Journal of Physical Chemistry C, Vol. 114, pp. 6849-6853, 2010, and methods of forming a titanium oxide layer disclosed in Thin Solid Film, Vol. 517, pp. 3766-3769, 2007 and in Advanced Materials, Vol. 19, pp. 2445-2449, 2007 are particularly preferable.

### Metal Electrode Layer

The metal electrode layer is usually a negative electrode. The negative electrode is usually made of a metal having a relatively small work function. Examples of such a metal include aluminum, magnesium, silver, silver-magnesium alloy, etc. An electron-injection layer made of lithium fluoride, lithium oxide, or the like, having a thickness in the range from 0.1 to 5 nm may be provided on the side of the metal electrode layer nearer to the n-type oxide semiconductor layer.

The thickness of the negative electrode is in the range from 10 nm to 500 nm, or preferably in the range from 50 nm to 300 nm. Formation of the oxide semiconductor layer can be achieved by any of various wet film-forming methods, dry film-forming methods, such as vapor deposition or sputtering, a transfer method, printing, etc. Among them, printing, inkjet printing and vapor deposition are preferable.

Patterning during the formation of the negative electrode may be achieved, for example, by printing or inkjet printing. Alternatively, the patterning may be achieved by chemical etching, such as photolithography, physical etching using a laser, or the like, or vacuum deposition or sputtering using layers of masks.

In the invention, the position where the negative electrode is formed is not particularly limited. The negative electrode may be formed on the entire organic layer or part of the organic layer.

### Upper Sealing Member

The organic electronic device is required to be isolated from external atmosphere by the organic-inorganic layered barrier layer on the plastic substrate and the upper sealing member, which is described below. The upper sealing member includes a gas barrier layer. The upper sealing member may include a protective layer, an adhesive layer, or a plastic support.

A preferred structure example of the upper sealing member includes, in order from the metal electrode side, the protective layer, the adhesive layer, the gas barrier layer and the plastic support.

### Protective Layer

The protective layer is usually made of a metal oxide, such as MgO, SiO, SiO₂, Al₂O₃, Y₂O₃ or TiO₂, a metal nitride, such as SiNₓ, a metal nitride oxide, such as SiNₓO_{y}, a metal fluoride, such as MgF₂, LiF, AlF₃ or CaF₂, or a polymer, such as polyethylene, polypropylene, polyvinylidene fluoride or polyparaxylylene. Among them, an oxide, a nitride or a nitride oxide of a metal is preferable, and an oxide, a nitride or a nitride oxide of silicon or aluminum are particularly preferable. The protective layer may be a single layer or a multi-layer structure of materials selected from the above-described materials.

The method for forming the protective layer is not particularly limited. For example, vacuum deposition, sputtering, reactive sputtering, MBE (molecular beam epitaxy), cluster ion beam, ion plating, plasma polymerization (high-frequency excitation ion plating), plasma CVD, laser CVD, thermal CVD, gas source CVD, vacuum ultraviolet CVD, coating, printing or a transfer method is applicable.

### Gas Barrier Layer

The gas barrier layer is not particularly limited as long as it has the gas barrier ability. Usually, the gas barrier layer is a layer of an inorganic material (which may also be referred to as “inorganic layer”). Typical examples of the inorganic material contained in the inorganic layer include an oxide, a nitride, an oxynitride, a carbide, a hydride, etc., of boron, magnesium, aluminum, silicon, titanium, zinc and tin. The inorganic material may be a pure material, or a mixture or a gradient material layer including different compositions. Among them, an oxide, a nitride or an oxynitride of aluminum, or an oxide, a nitride or an oxynitride of silicon is preferable.

The inorganic layer serving as the gas barrier layer may be a single layer or a layered structure. In the case where the gas barrier layer has a layered structure, the layered structure may include an inorganic layer and an organic layer, or a plurality of inorganic layers and a plurality of organic layer that are alternately disposed. The definitions of the organic layer and the inorganic layer are the same as those described above.

The thickness of the inorganic layer serving as the gas barrier layer is not particularly limited; however, it is usually in the range from 5 to 500 nm per layer, or preferably in the range from 10 to 200 nm per layer. The inorganic layer may have a layered structure including a plurality of sub-layers. In this case, the sub-layers may have the same composition or different compositions. Alternatively, as mentioned above, a layer without a clear interface between the inorganic layer and the organic polymer layer adjacent to each other, where one of different compositions changes over to the other of the compositions in a continuous manner in the thickness direction, as disclosed in U.S. Patent Application Publication No. 2004046497, may be applied.

### Adhesive Layer

The adhesive is not particularly limited; however, for example, an emulsion type adhesive, an adhesive for wax hot melt lamination, an adhesive for dry lamination, etc., are preferable.

An examples of the emulsion type adhesive is a coating agent in which a thermoplastic elastomer, LDPE, IO (ionomer), PVDC, PE (polyethylene) wax, or the like, is dispersed.

Examples of the adhesive for wax hot melt lamination include OPP (biaxially-oriented polypropylene) film coated with PVDC (polyvinylidene chloride resin), nylon film, PET film, PVA film, etc.

Examples of the adhesive for dry lamination include vinyl chloride-vinyl acetate copolymer, EVA (ethylene-vinyl acetate copolymer), ionomer copolymer, polyvinylidene chloride, ethylene-vinyl alcohol copolymer, cellulose nitrate, cellulose acetate, silicone, etc.

### Plastic Support

The definition of the plastic support is the same as that described above.

### Method for Providing Upper Sealing Member

First, the protective layer is provided on the metal electrode layer. A seal film including the gas barrier layer formed on a plastic support is made and the seal film is adhered onto the protective layer via an adhesive. In a case where the upper portion is not required to be transparent, a gas barrier film laminated with a metal foil may be adhered onto the protective layer.

### Others

The thickness of the organic electronic device of the invention is preferably in the range from 100 μm to 2 mm, or more preferably in the range from 200 μm to 1 μm.

In a case where a solar battery module is produced using the organic thin-layer solar battery of the invention, teachings in HAMAKAWA Yoshihiro, Taiyoko Hatsuden—Saishin-no-Gijutsu-to-Sisutemu (Photovoltaic Power Generation—the Latest Technology and System) (published by CMC Publishing Co., Ltd.), etc., can be referenced.

### EXAMPLES

Hereinafter, the present invention is more specifically described using examples. The materials, amounts of the materials used, ratios, contents of treatments, procedures, etc., shown in the following examples can be modified as appropriate without departing from the spirit of the invention. Therefore, the scope of the invention is not limited to the specific examples shown below.

### Example 1

The organic-inorganic layered barrier layer 11 was formed on one side of a polyethylene terephthalate film (which will hereinafter be referred to as “PET film”) 12 having a thickness of 180 μm, which was the plastic support, and the transparent electrode layer 13, the photoelectric conversion layer (organic active layer) 20, the n-type oxide semiconductor layer 25, the negative electrode (metal electrode layer) 26, and the upper sealing member 30 including a passivation layer, an adhesive layer and a barrier film were formed in layers on the other side of the and PET film 12 to produce an organic thin-film solar battery of Example 1 (see FIG. 1 for the layer structure).

### Formation of Barrier Layer 11

A polymerizable composition (a mixed solution of EB-3702 (13 g), available from Daicel-Cytec; LIGHT ACRYLATE TMP-A (6 g), available from Kyoeisha Chemical Co., Ltd.; KAYAMER PM-21 (1 g), available from Nippon Kayaku Co., Ltd.; an ultraviolet polymerization initiator, ESACURE KTO-46 (0.5 g), available from Lamberti; and 190 g of 2-butanone) was coated on the PET film with a wire bar. After drying, the organic layer was cured by being exposed to an ultraviolet ray from a high pressure mercury lamp (with a cumulative exposure dose of 1 J/cm²) in a chamber with an oxygen concentration of 0.1%, which was provided by nitrogen substitution, to form an organic layer having a thickness of 1.5 μm.

Using a sputtering apparatus, an inorganic layer (aluminum oxide layer) was formed on the organic layer. Aluminum was used as the target, argon was used as the discharge gas, and oxygen was used as the reaction gas. The film formation pressure was 0.1 Pa, and the achieved film thickness was 40 nm.

The above-described polymerizable composition was coated on the resulting layered body and cured in the same manner as described above to form an organic layer having a thickness of 1.5 μm.

In this manner, the barrier layer formed by three layers including the organic layer, the inorganic layer and the organic layer was formed on the PET film. The moisture vapor transmission rate at a temperature of 40° C. and a relative humidity of 90% of the PET film having this barrier layer was measured using a moisture vapor transmission rate measuring device (PERMATRAN-W3/31, available from MOCON) and found to be below the detection limit value (0.005 g/m²/day) of this measurement.

### Formation of Transparent Electrode Layer 13

Using a sputtering apparatus, an ITO layer was formed as the transparent electrode layer 13 on the surface of the PET film 12 opposite from the barrier layer 11. The ITO layer had a thickness of 300 nm and a sheet resistance of 30Ω/sq.

On the surface of the thus formed transparent electrode layer, an aqueous dispersion of polyethylenedioxythiophene/polystyrene sulfonate (abbreviated as PEDOT-PSS) (P.VP.AI4083, available from H. C. Starck) was spin-coated. Then, this film was dried by heating at 100° C. for 20 minutes to form an electron-blocking layer. The electron-blocking layer had a thickness of 40 nm.

### Coating of Photoelectric Conversion Layer 20

A bulk hetero layer was formed as the photoelectric conversion layer 20. In 1 ml of chlorobenzene, 20 mg of P3HT (poly-3-hexylthiophene, LISICON SP-001 (trade name), available from Merck) and 14 mg of PCBM ([6,6]-phenyl C₆₁-butyric acid methyl ester, NANOMSPECTRA E-100H (trade name), available from Frontier Carbon) were dissolved to prepare a bulk hetero layer coating solution. This coating solution was spin-coated on the surface of the transparent conductive film to form the bulk hetero layer. The rotational speed of the spin coater was 500 rpm, and the dry film thickness was 180 nm.

### Annealing

Thereafter, this sample was heated at 130° C. for 15 minutes using a hot plate.

### Coating of Oxide Semiconductor Layer 25

A coating solution containing a mixture of 20 μl of titanium tetraisopropoxide and 4 ml of dehydrated ethanol was spin-coated on the bulk hetero layer. The rotational speed of the spin coater was 2000 rpm. This film was dried in the atmosphere for 1 hour to provide an n-type oxide semiconductor layer (electron-transporting layer) formed by amorphous titanium oxide having a thickness of 7 nm.

### Vapor Deposition of Negative Electrode 26

Aluminum was vapor-deposited to a thickness of 100 nm on the n-type oxide semiconductor layer 25 to form the negative electrode 26. A mask deposition process was performed such that an effective area for photoelectric conversion of 25 cm² was provided.

### Formation of Upper Sealing Member

On the sample after the formation of the negative electrode, the PET film having the barrier layer was placed using EVA for sealing solar batteries available from Tohcello (SOLAREVA (trade name), an ethylene-vinyl acetate copolymer with a heat-curing agent mixed therein, with a thickness of 0.5 mm) as an adhesive, and vacuum lamination was performed at 140° C. At this time, the PET film was placed such that the barrier layer was positioned on the EVA side.

In this manner, an organic thin-film solar battery (P-1) of Example 1 was completed.

### Example 2

An organic thin-film solar battery of Example 2 had the same layer structure as that of Example 1, except that the structure of the transparent electrode layer 13 was different from that of Example 1. The transparent conductive layer 13 of this example included a conductive stripe and a transparent conductive material layer. The organic thin-film solar battery (P-2) of Example 2 was produced by the same production method as that of Example 1 except the method for forming the transparent conductive layer 13. The method for forming the transparent conductive layer 13 of Example 2 was as follows.

### Formation of Transparent Conductive Layer 13

On the surface of the 100 mm×100 mm PET film 12 opposite from the barrier layer 11, a conductive stripe, which was formed by a plurality of conductive lines having a line width of 0.3 mm and a line length of 90 mm and arranged at an interval of 4 mm, and two bus lines having a line width of 2 mm and a line length of 90 mm and arranged at a line interval of 50 mm, which were perpendicular to the conductive stripe, were simultaneously formed by a mask deposition process. The material forming the conductive lines and the bus lines was silver, and the film thickness was 100 nm.

On the surface of the thus formed film, an aqueous dispersion of polyethylenedioxythiophene/polystyrene sulfonate (abbreviated as PEDOT-PSS) (ORGACON S-305, available from Agfa) was spin-coated. Then, this film was dried by heating at 100° C. for 20 minutes to form a conductive polymer layer. The thickness of the conductive polymer layer was 100 nm. It should be noted that the electron-blocking layer was not provided in this example.

### Example 3

An organic thin-film solar battery of Example 3 had the same structure as that of Example 2, except that the barrier layer 11 was disposed between the support 12 and the transparent electrode layer 13 (see FIG. 2). The organic thin-film solar battery (P-3) of Example 3 was produced by the same production method as that of Example 2 except that the transparent electrode layer 13 was formed on the barrier layer 11.

### Example 4

An organic thin-film solar battery of Example 4 had the same layer structure as that of Example 3, except that the structure of the transparent electrode layer 13 was different from that of Example 3. The transparent conductive layer 13 of this example included a conductive stripe and a transparent conductive material layer. The organic thin-film solar battery (P-4) of Example 4 was produced by the same production method as that of Example 3 except the method for forming the transparent conductive layer 13. The method for forming the transparent electrode layer 13 of Example 4 was as follows.

### Formation of Transparent Conductive Layer 13

On the surface of the 100 mm×100 mm PET film 12 opposite from the barrier layer 11, a conductive stripe, which was formed by a plurality of conductive lines having a line width of 0.3 mm and a line length of 90 mm and arranged at an interval of 4 mm, and two bus lines having a line width of 2 mm and a line length of 90 mm and arranged at a line interval of 50 mm, which were perpendicular to the conductive stripe, were simultaneously formed by a mask deposition process. The material forming the conductive lines and the bus lines was silver, and the film thickness was 100 nm.

On the surface of the thus formed film, an aqueous dispersion of polyethylenedioxythiophene/polystyrene sulfonate (abbreviated as PEDOT-PSS) (ORGACON S-305, available from Agfa) was spin-coated. Then, this film was dried by heating at 120° C. for 20 minutes to form a conductive polymer layer. The thickness of the conductive polymer layer was 100 nm.

On this conductive polymer layer, an aqueous dispersion of polyethylenedioxythiophene/polystyrene sulfonate (abbreviated as PEDOT-PSS) (P.VP.AI4083, available from H. C. Starck) was spin-coated. Then, this film was dried by heating at 100° C. for 20 minutes to form an electron-blocking layer. The electron-blocking layer had a thickness of 40 nm.

### Example 5

An organic thin-film solar battery of Example 5 had the same layer structure as that of Example 4, except that the conductive stripe was made of a different material from that of Example 4. The conductive stripe of this example was made of copper. The organic thin-film solar battery (P-5) of Example 5 was produced by the same production method as that of Example 4, except the material forming the conductive stripe.

### Comparative Example 1

An organic thin-film solar battery of Comparative Example 1 had the same layer structure as that of Example 1, except that the n-type oxide semiconductor layer was not provided. Namely, the barrier layer was formed on one side of a PET film having a thickness of 180 μm, and the transparent conductive layer, the photoelectric conversion layer, the negative electrode, and the upper sealing member including a passivation layer, an adhesive layer and a barrier film were formed in layers on the other side of the PET film to produce the organic thin-film solar battery (S-1) of Comparative Example 1.

The production method was almost the same as that of Example 1. While the annealing was performed after the formation of the photoelectric conversion layer and before the formation of the n-type semiconductor layer in Example 1, annealing was not performed after the formation of the photoelectric conversion layer in Comparative Example 1. In Comparative Example 1, the negative electrode was formed on the photoelectric conversion layer, and the sample after the formation of the negative electrode was heated as annealing at 130° C. for 15 minutes using a hot plate. The other points were the same as those of Example 1.

### Comparative Example 2

An organic thin-film solar battery of Comparative Example 2 had the same layer structure as that of Comparative Example 1, except that the structure of the transparent electrode layer was different from that of Comparative Example 1. The transparent conductive layer of this comparative example included a conductive stripe and a transparent conductive material layer, similarly to Example 2. Namely, the organic thin-film solar battery of Comparative Example 2 had the same structure as that of the organic thin-film solar battery of Example 2, except that the n-type oxide semiconductor layer was not provided. The organic thin-film solar battery (S-2) of Comparative Example 2 was produced by the same production method as that of Comparative Example 1, except that the transparent electrode layer was formed by the same method as that of Example 2.

### Comparative Example 3

An organic thin-film solar battery of Comparative Example 3 had the same structure as that of Comparative Example 2, except that the barrier layer 11 was disposed between the support 12 and the transparent electrode layer 13 (see FIG. 2). Namely, the organic thin-film solar battery of Comparative Example 3 had the same structure as that of the organic thin-film solar battery of Example 3, except that the n-type oxide semiconductor layer was not provided. The organic thin-film solar battery (S-3) of Comparative Example 3 was produced by the same production method as that of Comparative Example 2, except that the transparent electrode layer was formed on the barrier layer.

### Comparative Example 4

An organic thin-film solar battery of Comparative Example 4 had the same structure as that of the organic thin-film solar battery of Example 4, except that the n-type oxide semiconductor layer was not provided. The organic thin-film solar battery (S-4) of Comparative Example 4 was produced by the same production method as that of Comparative Example 3, except that the transparent electrode layer was formed by the same method as that of Example 4.

### Comparative Example 5

An organic thin-film solar battery of Comparative Example 5 had the same structure as that of the organic thin-film solar battery of Example 5, except that the n-type oxide semiconductor layer was not provided. The organic thin-film solar battery (S-5) of Comparative Example 5 was produced by the same production method as that of Comparative Example 4, except the material forming the conductive stripe.

### Comparative Example 6

An organic thin-film solar battery of Comparative Example 6 had the same layer structure as that of Example 1, except that the organic-inorganic layered barrier layer was not provided. The organic thin-film solar battery (S-6) of Comparative Example 6 was produced by forming, on a PET film having a thickness of 180 μm, the transparent conductive layer, the photoelectric conversion layer, the n-type oxide semiconductor layer, the negative electrode, and the upper sealing member including a passivation layer, an adhesive layer and a barrier film in layers by the same method as that of Example 1.

### Comparative Example 7

An organic thin-film solar battery of Comparative Example 7 had the same structure as that of Example 1, except that glass having a thickness of 0.7 mm was used as the support, and that the organic-inorganic layered barrier layer and the n-type oxide semiconductor layer were not provided. Namely, in Comparative Example 7, the transparent conductive layer, the photoelectric conversion layer, the negative electrode, and the upper sealing layer including a passivation layer, an adhesive layer and a barrier film were formed in layers on the 0.7 mm-thick glass. The organic thin-film solar battery (S-7) of Comparative Example 7 was produced by the same production method as that of Comparative Example 1, except that the step of forming the barrier layer was not included.

### Measurement of Power Generation Efficiency

While applying simulated sunlight of AM 1.5G and 80 mW/cm² using a solar simulator, L12, available from Peccell Technologies, to the organic thin-film solar batteries obtained in Examples 1 to 5 and Comparative Examples 1 to 7, values of generated current in the voltage range from −0.1V to 1.0V were measured using a source measure unit (SMU2400, available from Keithley). The resulting current-voltage characteristics were evaluated using an I-V curve analyzer available from Peccell Technologies, and values of conversion efficiency (%) were calculated as initial battery characteristics of characteristics parameters. The results of the measurement are shown in Table 1 below.

### Measurement of Storage Stability

Next, after the devices were left in a high temperature and high humidity room at a temperature of 40° C. and a relative humidity of 90% for 100 hours, the current-voltage characteristics were measured while applying the simulated sunlight of AM 1.5 and 80 mW/cm², and a conversion efficiency retention rate of each device was measured as an index of storage stability according to the equation below:

The conversion efficiency retention rate(%)={(the conversion efficiency after the device was left in the high temperature and high humidity room)/(the conversion efficiency immediately after the device was produced)}×100

The results are shown in Table 1.

TABLE 1

| | | Organic-inorganic layered | Transparent electrode | n-type oxide | Conversion | Efficiency |
|---|---|---|---|---|---|---|
| Sample No. | Support | barrier layer | layer | semiconductor | efficiency (%) | retention rate (%) |
| Example 1: P-1 | PET | provided (outer side) | ITO | TiOₓ layer | 1.6 | 80 |
| Example 2: P-2 | PET | provided (outer side) | Ags/S305 | TiOₓ layer | 2.5 | 80 |
| Example 3: P-3 | PET | provided (device side) | Ags/S305 | TiOₓ layer | 2.6 | 85 |
| Example 4: P-4 | PET | provided (device side) | Ags/S305/AI4083 | TiOₓ layer | 2.5 | 85 |
| Example 5: P-5 | PET | provided (device side) | Cus/S305/AI4083 | TiOₓ layer | 2.4 | 85 |
| Comp. Example 1: S-1 | PET | provided (outer side) | ITO | not provided | 0.7 | — |
| Comp. Example 2: S-2 | PET | provided (outer side) | Ags/S305 | not provided | 0.1 | — |
| Comp. Example 3: S-3 | PET | provided (device side) | Ags/S305 | not provided | 1.1 | 40 |
| Comp. Example 4: S-4 | PET | provided (device side) | Ags/S305/AI4083 | not provided | 1.0 | 40 |
| Comp. Example 5: S-5 | PET | provided (device side) | Cus/S305/AI4083 | not provided | 1.0 | 40 |
| Comp. Example 6: S-6 | PET | not provided | ITO | TiOₓ layer | 1.3 | 50 |
| Comp. Example 7: S-7 | glass | — | ITO | not provided | 2.4 | 85 |

As can be seen from the results shown in Table 1, the organic thin-film solar batteries (P-1 to P-5) of the examples of the invention exhibited high conversion efficiency (power generation efficiency) and high efficiency retention rate (high storage stability).

What is claimed is:

1. An organic electronic device comprising at least an organic-inorganic layered barrier layer, a plastic support, a transparent electrode layer, an organic active layer, a metal electrode layer and an upper sealing member, and contains a strong acid polymer,
the organic electronic device further comprising an n-type oxide semiconductor layer that is provided adjacent to the metal electrode layer on a side of the metal electrode layer nearer to the plastic support.

2. The organic electronic device as claimed in claim 1, wherein the n-type oxide semiconductor is titanium oxide or zinc oxide.

3. The organic electronic device as claimed in claim 1, wherein the strong acid polymer is polystyrene sulfonate.

4. The organic electronic device as claimed in claim 1, wherein the strong acid polymer is polyethylenedioxythiophene/polystyrene sulfonate complex.

5. The organic electronic device as claimed in claim 1, wherein the strong acid polymer is provided in the transparent electrode layer or adjacent to the transparent electrode layer.

6. The organic electronic device as claimed in claim 1, wherein the transparent electrode layer comprises a combination of a conductive stripe formed by a plurality of conductive lines arranged in a stripe pattern and a transparent conductive material.

7. The organic electronic device as claimed in claim 6, wherein the conductive lines are made of silver or copper.

8. The organic electronic device as claimed in claim 1, wherein the organic-inorganic layered barrier layer is provided between the plastic support and the transparent electrode layer.

9. The organic electronic device as claimed in claim 8, wherein a layer of the organic-inorganic layered barrier layer adjacent to the transparent electrode layer is an organic layer.

10. The organic electronic device as claimed in claim 1, wherein the organic active layer is a photoelectric conversion layer, and
the organic electronic device functions as an organic thin-film solar battery.

11. The organic electronic device as claimed in claim 10, wherein the photoelectric conversion layer is a bulk hetero layer.
